(19) United States
(12) Patent Application Publication
(10) Pub. No.: US 2018/0076391 A1
(43) Pub. Date: Mar. 15, 2018

(54) ORGANIC ELECTROLUMINESCENT DEVICES

(71) Applicant: E-RAY OPTOELECTRONICS TECHNOLOGY CO., LTD., Taoyuan City (TW)

(72) Inventors: Heh-Lung Huang, Taoyuan City (TW); Po-Wei Hsu, Taoyuan City (TW); Chi-Jen Lin, Taoyuan City (TW)

(21) Appl. No.: 15/471,061

(22) Filed: Mar. 28, 2017

(30) Foreign Application Priority Data
Sep. 9, 2016 (TW) 105129293

(51) Int. Cl. H01L 51/00; C09K 11/02; C09K 11/06

(52) U.S. Cl. CPC H01L 51/0054; C09K 11/02; H01L 51/5004; H01L 51/0058; H01L 51/0072; C09K 11/06

(57) ABSTRACT

An organic electroluminescent device includes a cathode, an anode, and a light emitting layer interposed between the anode and cathode, wherein the light emitting layer includes a host emitter and a guest emitter represented by formula (I):

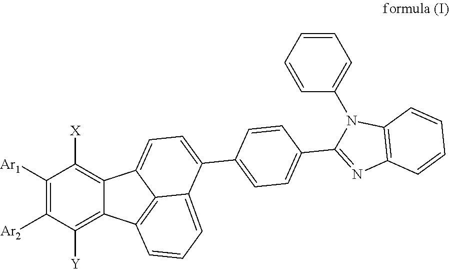

wherein X and Y independently represent hydrogen, or an aryl group or a heteroaryl group having 5 to 10 carbon atoms, X and Y are the same or different, and Ar₁ and Ar₂ independently represent hydrogen, or an unsubstituted or substituted aryl group having 5 to 12 carbon atoms, or Ar₁ and Ar₂ form a fused aromatic ring system together with an attached carbon atom.

### BACKGROUND

### 1. Technical Field

The present disclosure relates to organic electroluminescent devices, and more particularly, to a blue light organic electroluminescent device that comprises a guest emitter having a fused ring therein.

### 2. Description of Related Art

There has been an increasing interest in organic electroluminescent devices (OELDs) in the recent years, because the devices have characteristics, such as, self-light emittance, low driving voltages, high efficiency, brilliant luminance, thinness and broad color ranges, and suitability for displays and illuminating applications.

A typical OELD includes an anode, a hole transport layer, a light emitting layer, an electron transport layer and a cathode, which are sequentially deposited by a vacuum deposition method or coating method. When a current is applied to an OELD, the anode injects holes, and the cathode injects electrons into (a plurality of) organic layers. The injected holes enter a light emitting layer through a hole transport layer, and the electrons migrate to a light emitting layer through an electron transport layer. In a light emitting layer, the conjunction of electrons and holes forms “excitons,” and light is emitted when the excitons relax through a photo emissive mechanism.

Currently, OELDs emitting red, yellow and green lights mainly use phosphorescent guest emitters light emitting materials. As for blue light OELDs, fluorescent guest emitters are mainly used due to the short lifetime and colorimetric purity of blue phosphorescence. Accordingly, there is an urgent need for the development of a material, with an extended lifetime and improved luminous efficiency, for blue fluorescent OELDs.

### SUMMARY

An object of the present disclosure is to provide a blue fluorescent OELD with a longer lifetime, a low driving voltage, and high colorimetric purity.

The present disclosure provides an organic electroluminescent device, comprising: a cathode, an anode, and a light emitting layer interposed between the anode and cathode, wherein the light emitting layer comprises a host emitter and a guest emitter in an amount of 1 wt % to 10 wt %, based on a total weight of the light emitting layer, and the guest emitter is a compound represented by formula (I):

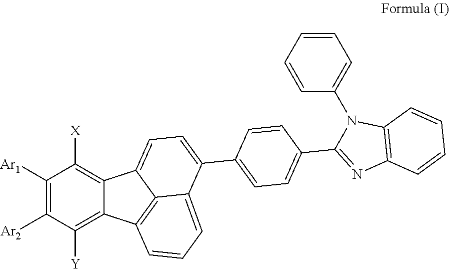

wherein X and Y independently represent hydrogen, or an aryl group or a heteroaryl group having 5 to 10 carbon atoms; X and Y are the same or different; and Ar₁ and Ar₂ independently represent hydrogen, or an unsubstituted or substituted aryl group having 5 to 12 carbon atoms; or Ar₁ and Ar₂ form a fused aromatic ring system together with an attached carbon atom.

### BRIEF DESCRIPTION OF THE DRAWINGS

FIG. 1 is a cross-sectional view illustrating an organic electroluminescent device according to an embodiment of the present disclosure;

FIG. 2 is a cross-sectional view illustrating an organic electroluminescent device according to another embodiment of the present disclosure;

FIG. 3 shows an electroluminescent spectrum of a blue fluorescent organic electroluminescent device according to the present disclosure;

FIG. 4 shows an electroluminescent spectrum of another blue fluorescent organic electroluminescent device according to the present disclosure; and

FIG. 5 shows an electroluminescent spectrum of a top-emitting blue fluorescent organic electroluminescent device according to the present disclosure.

### DETAILED DESCRIPTION OF THE EMBODIMENTS

The following specific embodiments are provided to illustrate the present disclosure for those skilled in the art, so as to enhance the understanding of the advantages and effects disclosed in the specification of the present disclosure.

All of the ranges and values disclosed herein can be included and combined. For example, when any numerical value, such as an integer or a point value, falls within the range described herein, a sub-range can be deducted from a point value or a numerical value as an upper limit or a lower limit. In addition, the groups listed herein, e.g., groups or the substituents of X, Y, Ar₁ and Ar₂, can all be combined in formula (I) with other groups.

The organic electroluminescent device according to the present disclosure comprises: a cathode, an anode, and a light emitting layer interposed between the anode and cathode, wherein the light emitting layer comprises a host emitter and a guest emitter in an amount of 1 wt % to 10 wt %, based on a total weight of the light emitting layer, and the guest emitter is a compound represented as a formula (I):

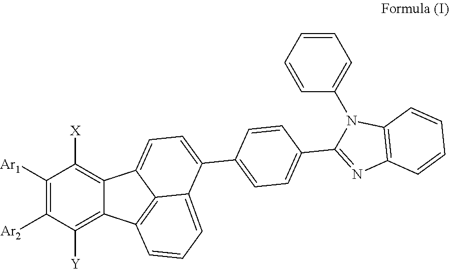

wherein X and Y independently represent hydrogen, or an aryl or a heteroaryl group having 5 to 10 carbon atoms, X and Y are the same or different; and Ar₁ and Ar₂ independently represent hydrogen, or an unsubstituted or substituted aryl group having 5 to 12 carbon atoms; or Ar₁ and Ar₂ form a fused aromatic ring system together with an attached carbon atom.

In an embodiment, the aryl group having 5 to 10 carbon atoms is a phenyl group or naphthyl group. In addition, X or Y can be a phenyl group or naphthyl group. Specifically, when, in the formula (I), X is a phenyl group or naphthyl group, the groups described elsewhere in the specification can be selected as Y, Ar₁ and Ar₂. Also, when, in the formula (I), Y is a phenyl group or naphthyl group, groups described elsewhere in the specification can be selected as X, Ar₁ and Ar₂.

In another embodiment, the heteroaryl group having 5 to 10 carbon atoms is a pyridyl group or

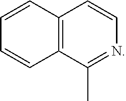

The pyridyl group may be linked at 2-, 3- or 4-position. In addition, X or Y may be a pyridyl group or

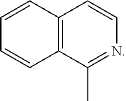

Specifically, when, in formula (I), X is a pyridyl group or

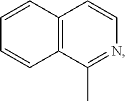

the groups described elsewhere in the specification can be selected as Y, Ar₁ and Ar₂. Also, when, in the formula (I), Y is a pyridyl group or

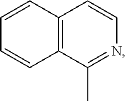

the groups described elsewhere in the specification can be selected as X, Ar₁ and Ar₂.

In an embodiment, Ar₁ and Ar₂ independently represent hydrogen or a phenyl group; or the Ar₁ and Ar₂ form a fused benzene ring together with an attached carbon atom. For example, when Ar₁ is hydrogen or a phenyl group, or Ar₁ and Ar₂ form a fused benzene ring together with an attached carbon atom, the groups described elsewhere in the specification can be selected as X, Y and Ar₂. Also, when Ar₂ is hydrogen or a phenyl group, or Ar₁ and Ar₂ form a fused benzene ring together with an attached carbon atom, the groups described elsewhere in the specification can be selected as X, Y and Ar₁.

Preferred examples of the aforementioned compounds represented by formula (I) are preferably selected from, but not limited to, compounds A-L as follows.

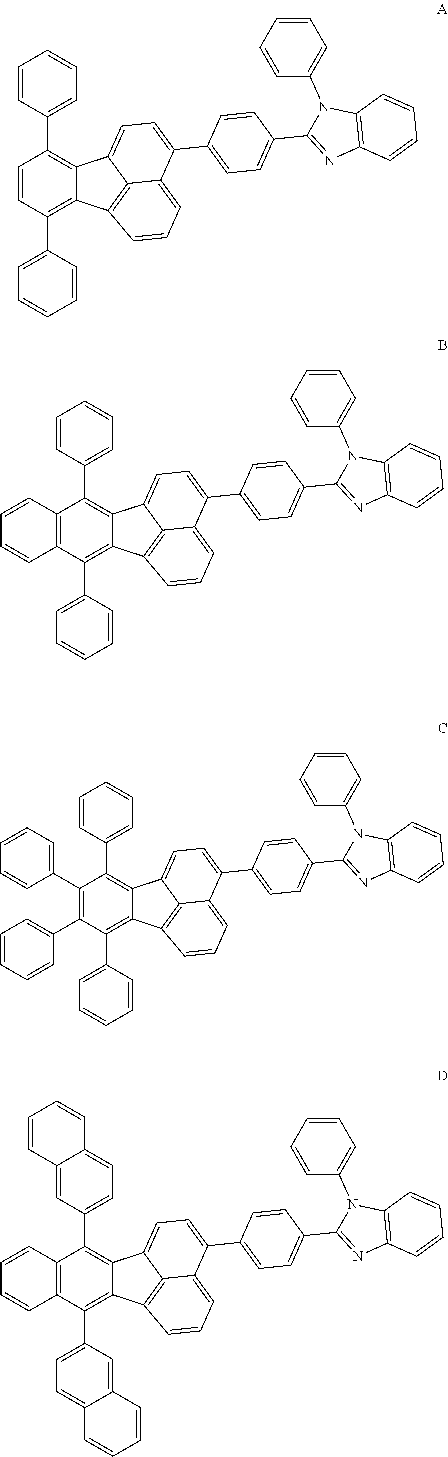 [SMILES: c1ccc(-c2ccc(-c3ccccc3)c3c2-c2cccc4c(-c5ccc(-c6nc7ccccc7n6-c6ccccc6)cc5)ccc-3c24)cc1 ; c1ccc(-c2c3c(c(-c4ccccc4)c4ccccc24)-c2ccc(-c4ccc(-c5nc6ccccc6n5-c5ccccc5)cc4)c4cccc-3c24)cc1 ; c1ccc(-c2c(-c3ccccc3)c(-c3ccccc3)c3c(c2-c2ccccc2)-c2cccc4c(-c5ccc(-c6nc7ccccc7n6-c6ccccc6)cc5)ccc-3c24)cc1 ; c1ccc(-n2c(-c3ccc(-c4ccc5c6c(cccc46)-c4c-5c(-c5ccc6ccccc6c5)c5ccccc5c4-c4ccc5ccccc5c4)cc3)nc3ccccc32)cc1]

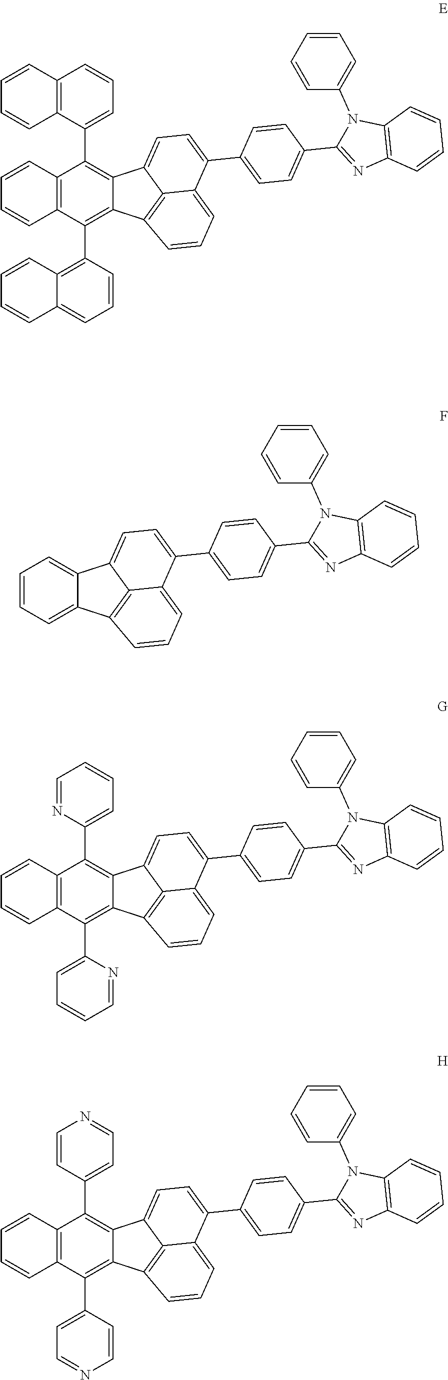 [SMILES: c1ccc(-n2c(-c3ccc(-c4ccc5c6c(cccc46)-c4c-5c(-c5cccc6ccccc56)c5ccccc5c4-c4cccc5ccccc45)cc3)nc3ccccc32)cc1 ; c1ccc(-n2c(-c3ccc(-c4ccc5c6c(cccc46)-c4ccccc4-5)cc3)nc3ccccc32)cc1 ; c1ccc(-n2c(-c3ccc(-c4ccc5c6c(cccc46)-c4c-5c(-c5ccccn5)c5ccccc5c4-c4ccccn4)cc3)nc3ccccc32)cc1 ; c1ccc(-n2c(-c3ccc(-c4ccc5c6c(cccc46)-c4c-5c(-c5ccncc5)c5ccccc5c4-c4ccncc4)cc3)nc3ccccc32)cc1]

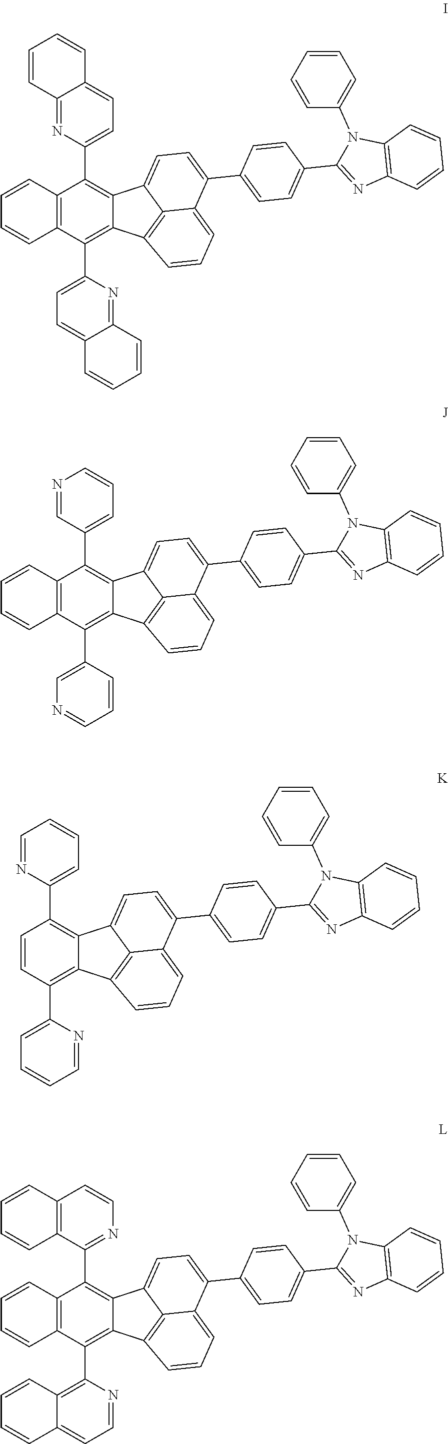 [SMILES: c1ccc(-n2c(-c3ccc(-c4ccc5c6c(cccc46)-c4c-5c(-c5ccc6ccccc6n5)c5ccccc5c4-c4ccc5ccccc5n4)cc3)nc3ccccc32)cc1 ; c1ccc(-n2c(-c3ccc(-c4ccc5c6c(cccc46)-c4c-5c(-c5cccnc5)c5ccccc5c4-c4cccnc4)cc3)nc3ccccc32)cc1 ; c1ccc(-n2c(-c3ccc(-c4ccc5c6c(cccc46)-c4c(-c6ccccn6)ccc(-c6ccccn6)c4-5)cc3)nc3ccccc32)cc1 ; c1ccc(-n2c(-c3ccc(-c4ccc5c6c(cccc46)-c4c-5c(-c5nccc6ccccc56)c5ccccc5c4-c4nccc5ccccc45)cc3)nc3ccccc32)cc1]

Preparations of aryl substituted-benzofluoranthene can be referred to the following references, e.g., the Journal of American Chemical Society (the Journal of American Chemical Society 1949, vol. 71 (6), p. 1917), and the Journal of Nanoscience and Nanotechnology (the Journal of Nanoscience and Nanotechnology 2008, vol. 8(9), p. 4787). Symmetrical 1,3-diarylisobenzofurans as an initial material of benzofluoranthene may be prepared via the processes provided in Synlett (Synlett 2006, 13, p. 2035). Then, the material may be converted to bromo analogues of aryl substituted-benzofluoranthene via processes provided in various references.

A compound represented by formula (I) is synthesized by a scheme showing a Suzuki coupling reaction of bromofluoranthene and 4-(1-phenyl-1H-benzo[d]imidazol-2-yl)phenylboronic acid below.

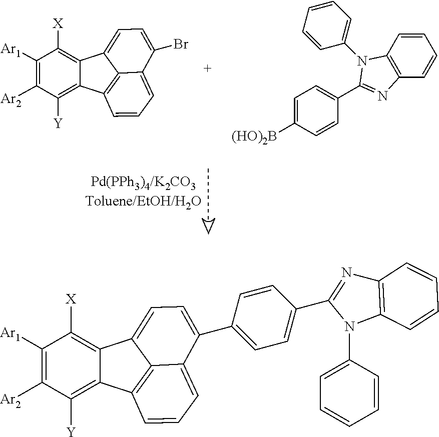

In an embodiment, calculated from a total weight of a light emitting layer of an organic electroluminescent device of the present disclosure, the compound represented by formula (I) is in an amount of 1 wt % to 10 wt %, or 2 wt % to 6 wt %. For example, calculated from a total weight of the light emitting layer, the compound represented by formula (I) is in an amount of 1 wt %, 2 wt %, 3 wt %, 4 wt %, 5 wt %, 6 wt %, 7 wt %, 8 wt %, 9 wt % or 10 wt %.

In an embodiment, a HOMO-LUMO energy gap of the compound represented by formula (I) is from 2.7 to 2.9 eV. For example, a HOMO-LUMO energy gap of the compound represented by formula (I) is 2.7 eV, 2.71 eV, 2.75 eV, 2.81 eV, 2.85 eV or 2.9 eV.

In another embodiment, the organic electroluminescent device further comprises a first hole transport layer, interposed between the light emitting layer and the anode, having a first hole transport material; and a second hole transport layer, interposed between the light emitting layer and the first hole transport layer, having a second hole transport material. A HOMO energy level of the first hole transport material is from 5.1 to 5.29 eV, for example, 5.1 eV, 5.2 eV, 5.14 eV, 5.16 eV, 5.18 eV, 5.2 eV, 5.22 eV, 5.24 eV, 5.26 eV, 5.28 and 5.29 eV. A HOMO energy level of the second hole transport material is from 5.3 to 5.7 eV, for example, 5.3 eV, 5.31 eV, 5.33 eV, 5.35 eV, 5.37 eV, 5.39 eV to 5.61 eV, 5.63 eV, 5.65 eV, 5.69 eV and 5.7 eV. A HOMO energy level of the host emitter is from 5.7 to 5.9 eV, for example, 5.7 eV, 5.72 eV, 5.74 eV, 5.76 eV, 5.78 eV, 5.8 eV, 5.82 eV, 5.84 eV, 5.86 eV, 5.88 and 5.9 eV.

In yet another embodiment, the organic electroluminescent device further comprises a capping layer disposed on the cathode.

In yet another embodiment, the host emitter in the light emitting layer of the organic electroluminescent device is a fluorescent emitter.

In addition to the light emitting layer comprising the host emitter and the compound represented by formula (I), the organic electroluminescent device of the present disclosure further includes at least one organic layer interposed between an anode and a cathode on a substrate, wherein the organic layer may be one layer selected from the group consisting of a hole injection layer, an electron transport layer, an electron injection layer, a hole blocking layer, and an electron blocking layer.

The structure of the organic electroluminescent device of the present disclosure is illustrated below with reference to the drawings, but it is not limited thereto.

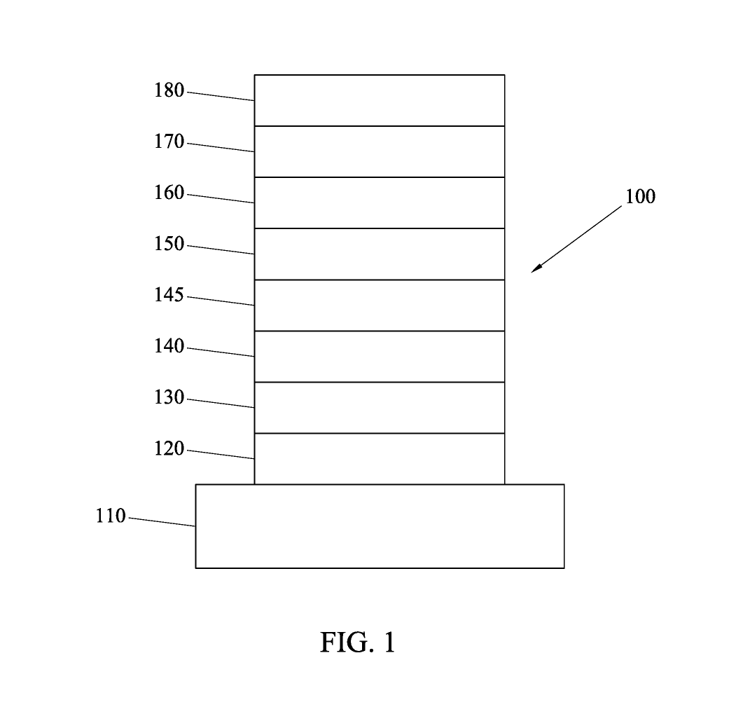

FIG. 1 is a cross-sectional schematic view of an organic electroluminescent device according to an embodiment of the present disclosure. An organic electroluminescent device 100 includes a substrate 110, an anode 120, a hole injection layer 130, a first hole transport layer 140, a second hole transport layer 145, a light emitting layer 150, an electron transport layer 160, an electron injection layer 170, and a cathode 180. The organic electroluminescent device 100 may be fabricated by depositing the aforementioned layers in sequence.

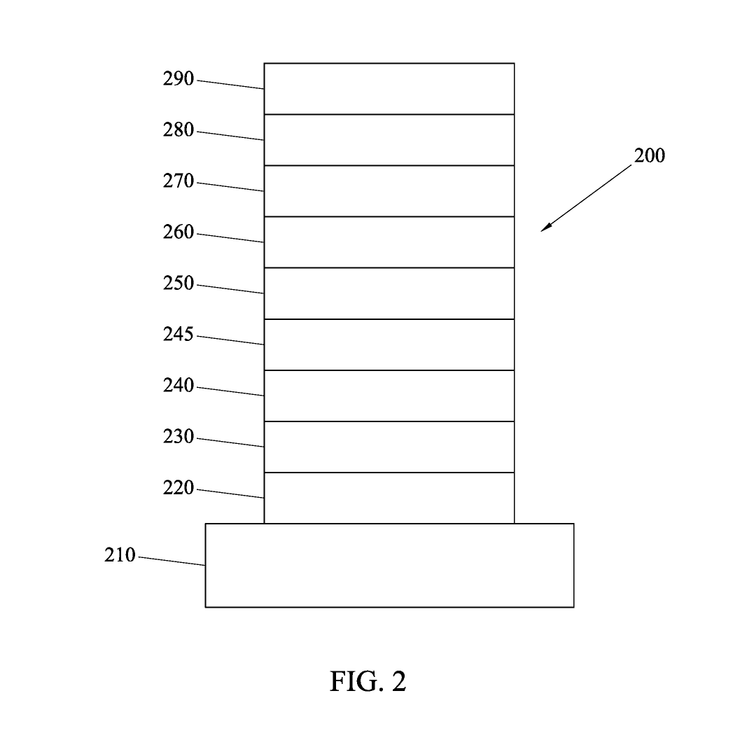

FIG. 2 is a cross-sectional schematic view of an organic electroluminescent device according to another embodiment of the present disclosure. An organic electroluminescent device 200 shown in FIG. 2 is similar to the one in FIG. 1. In addition to a substrate 210, an anode 220, a hole injection layer 230, a first hole transport layer 240, a second hole transport layer 245, a light emitting layer 250, an electron transport layer 260, an electron injection layer 270, a cathode 280 and a capping layer 290, a difference of FIG. 2 from FIG. 1 is that a capping layer 290 is disposed on a cathode 280.

Alternatively, an organic electroluminescent device may be fabricated using reverse structures of the devices shown in FIGS. 1 and 2. In such reverse structures, one or more layer(s) may be added or omitted as needed.

Materials used for a hole injection layer, a hole transport layer, an electron blocking layer, a hole blocking layer, a light emitting layer, an electron injection layer and a capping layer may be those conventionally used. For example, an electron transporting material for forming an electron transport layer differs from a material for forming a light emitting layer, and has the property of hole transport, and thereby facilitating hole mobility in an electron transport layer, and preventing carrier accumulation due to a difference in dissociation energy between a light emitting layer and an electron transport layer.

Moreover, Taiwanese Patent No. 1507396 to E-RAY OPTOELECTRONICS TECHONOLOGY CO LTD discloses a compound represented by formula (I), which is cited in its entirety by the present disclosure. However, in examples of the former patent, the compound represented by formula (I) is used in an electron transport layer, not in a light emitting layer.

Further, U.S. Pat. No. 5,844,363 discloses a flexible and transparent substrate in combination with an anode, which is incorporated herein by reference in its entirety. As disclosed in US Patent Publication No. 20030230980A1, an example of a p-type doped hole transport layer is m-MTDATA doped with F₄-TCNQ at a molar ratio of 50:1, which is incorporated herein by reference in its entirety. As disclosed in US Patent Publication No. 20030230980A1, an example of an n-type doped electron transport layer is BPhen doped with Li at a molar ratio of 1:1, which is incorporated herein by reference in its entirety. Entire disclosures of an exemplary cathode of U.S. Pat. Nos. 5,703,436 and 5,707,745 are incorporated herein by reference in their entirety, wherein the cathodes each has a thin layer of metal, e.g., Mg/Ag (Mg:Ag), with an overlaying transparent, electrically conductive and sputter-deposited ITO layer. Theory and use of each of blocking layers are described in U.S. Pat. No. 6,097,147 and US Patent Publication No. 20030230980, which are incorporated herein by reference in their entirety. An injection layer and a protective layer are described in US Patent Publication No. 20040174116A1, which is incorporated herein by reference in its entirety.

Structures and materials which are not specifically described may also be applied to the present disclosure, for example, an organic electroluminescent device comprising polymeric materials (PLEDs) disclosed in U.S. Pat. No. 5,247,190, which is incorporated herein by reference in its entirety. Furthermore, an organic electroluminescent device formed by stacking disclosed in U.S. Pat. No. 5,707,745 may be used, which is incorporated herein by reference.

Unless otherwise specified, any layers in the different examples may be deposited by any suitable method. For an organic layer, preferred methods include, for example, thermal evaporation and jet printing described in U.S. Pat. Nos. 6,013,982 and 6,087,196, which are incorporated herein by reference in their entirety; organic vapor phase deposition (OVPD) disclosed in U.S. Pat. No. 6,337,102, which is incorporated herein by reference in its entirety; and deposition by organic vapor jet printing (OVJP) disclosed in U.S. patent application Ser. No. 10/233,470, which is incorporated by reference in its entirety. Other suitable deposition methods include spin-coating and other solution-based processes. It is preferable to conduct solution-based processes in an environment containing nitrogen or inert gas. For other layers, preferred methods include thermal evaporation. Preferred patterning methods include, for example, deposition through a mask followed by cold welding, and patterning and deposition by integrated ink-jet and OVPD, as described in U.S. Pat. Nos. 6,294,398 and 6,468,819, which are incorporated by reference in their entirety. Certainly, other methods may be used. Materials to be deposited may be modified to be compatible with particular deposition methods.

The compound of formula (I) of the present disclosure may be used to make amorphous thin layers applied to an organic electroluminescent device by vacuum deposition or spin-coating. When the compound is used in any of the organic layers described above, it exhibits a longer lifetime and better thermal stability with high efficiency and a low driving voltage.

An organic electroluminescent device of the present disclosure is applicable to a single device, which is one having a structure of an array or a cathode and an anode arranged in an X-Y coordinates of the array. The present disclosure can provide a blue fluorescent organic electroluminescent device with significantly improved lifetime, colorimetric purity and a low driving voltage over the conventional devices. In addition, the organic electroluminescent device of the present disclosure can perform better and emit white light while being applied to full-color or multicolor display panels.

Properties and effects of the present disclosure are described in more details below with reference to examples. However, these detailed examples are merely used to illustrate the properties of the present disclosure. The present disclosure is not limited to these examples.

### Synthesis Example 1 (Synthesis of Compound C)

3-bromo-7,8,9,10-tetraphenylfluoranthene was prepared and synthesized by a process disclosed in the New Journal of Chemistry (the New Journal of Chemistry, 2010, 34, p. 2739).

Into a reaction flask, 20 g of 3-bromo-7,8,9,10-tetraphenylfluoranthene, 12.88 g of 4-(1-phenyl-1H-benzimidazol-2-yl)phenylboronic acid, and 1.97 g of Pd(PPh₃)₄, 300 mL of toluene, 150 mL of ethanol and 59.8 mL of a 2M K₂CO₃ solution were added. The mixture was stirred, and refluxed for 16 hours. After being quenched by water, the toluene layer was removed and washed with brine, and dried over anhydrous sodium sulfate. The solvent is removed under a reduced pressure to give 14.6 g of compound C, 1-phenyl-2-(4-(7,8,9,10-tetraphenylfluoranthen-3-yl)phenyl)-1H-benzo[d]imidazole, as a pale yellow solid.

¹H NMR (CDCl₃, δ): 7.90-7.96 (m, 2H), 7.80 (m, 2H), 7.70 (m, 2H), 7.58 (s, 1H), 7.46-7.55 (m, 12H), 7.30-7.32 (m, 13H), 7.22-7.26 (m, 6H).

### Example 1 (Fabrication of a Blue Fluorescent Organic Electroluminescent Device)

Prior to being loaded into an evaporation system, a substrate was cleaned and then degreased with a solvent and UV ozone. The substrate was then transferred into a vacuum deposition chamber for deposition of all layers on top of the substrate. By evaporation on a heated boat under a vacuum of about 10⁻⁶ Torr, each of the layers was deposited in sequence as shown in FIG. 1:

a) an indium tin oxide (ITO) layer, 1100 Å-thick;

b) a hole injection layer, 200 Å-thick, HI;

c) a hole transport layer, 1500 Å-thick, HT;

d) a second hole transport layer, 100 Å-thick, HT2;

e) a light emitting layer, 250 Å-thick, including a host emitter, BH, doped with 4 wt % of a guest emitter, compound C (BH is a product name from E-ray Optoelectronics Tech Co. Ltd, Taiwan);

f) an electron transport layer, 200 Å-thick, including compound ET doped with 50 wt % of quinolinolato-lithium (Liq);

g) an electron injection layer, 10 Å-thick, lithium fluoride (LiF); and

h) a cathode, about 1500 Å-thick, including Al.

The device structure of Example 1 may be denoted as ITO/HI/HT/HT2/compound C:BH/Liq:ET/LiF/Al.

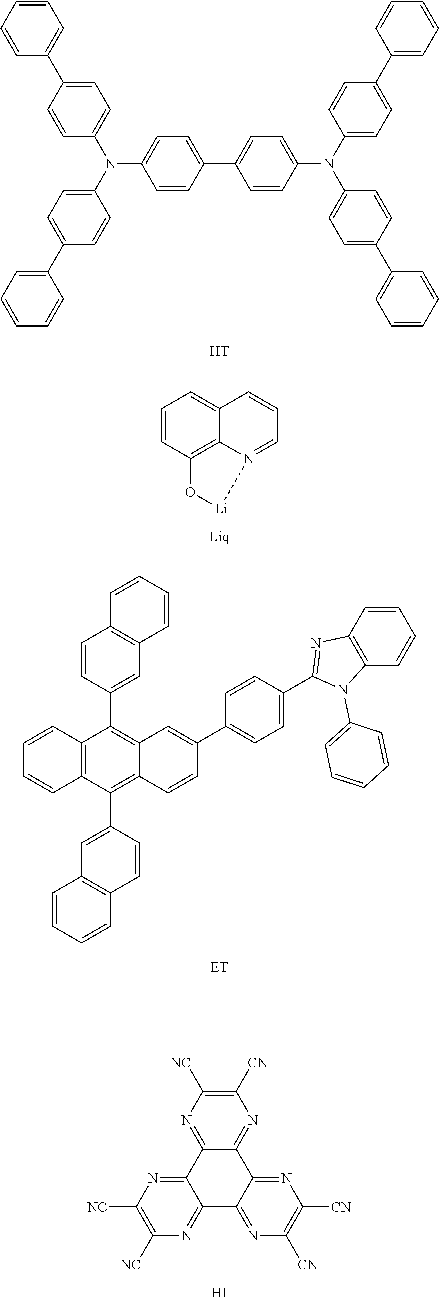

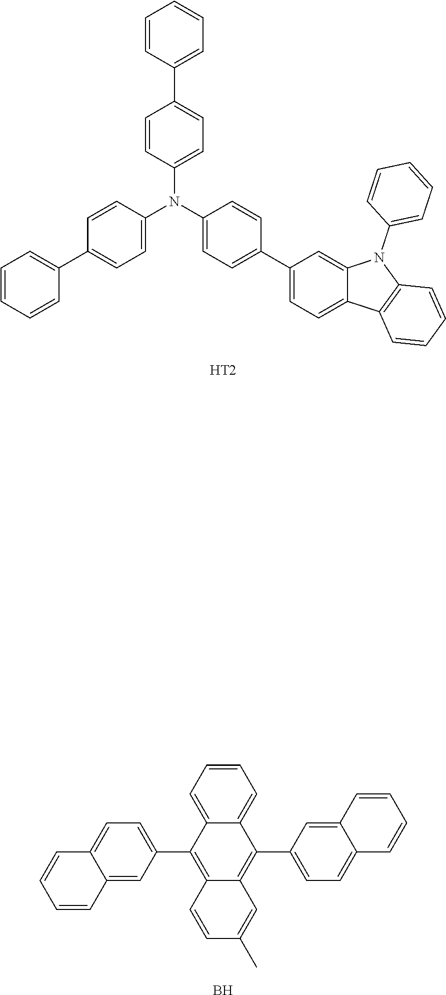

After deposition of each of the above layers, the device was transferred from the deposition chamber into a dry box for encapsulation, and subsequently encapsulated with an UV-curable sealant and a glass lid containing a moisture getter. The organic electroluminescent device has an emission area of 9 mm². Electroluminescent characteristics of all of the fabricated organic electroluminescent devices were evaluated with a constant current source (KEITHLEY 2400 Source Meter, made by Keithley Instruments, Inc., Cleveland, Ohio) and a photometer (PHOTO RESEARCH SpectraScan PR 650, made by Photo Research, Inc., Chatsworth, Calif.) at room temperature.

The operational lifetime (or stability) of the device was tested at room temperature and various initial luminance, depending on the color of the light emitting layer, by applying a constant current through the device. The color was reported with Commission Internationale de l'Eclairage (CIE) coordinates.

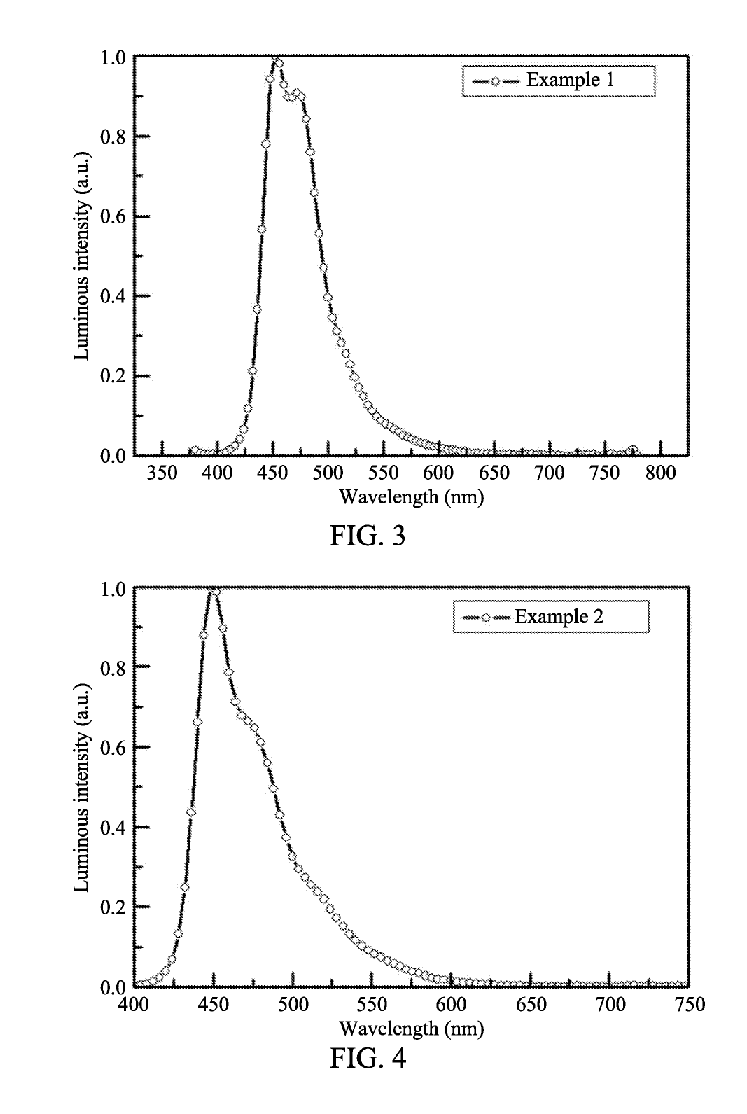

The organic electroluminescent device was connected to an external power source, and operated at a direct current voltage. Characteristics of light emission of the device were determined and shown in Table 1 below. With emitting a blue light, an electroluminescent spectrum of the organic electroluminescent device is as illustrated in FIG. 3.

TABLE 1

| | | | Current | Luminous | External | | |
|---|---|---|---|---|---|---|---|
| | Driving | Luminance | efficiency | efficiency | quantum | T95 | |
| | voltage | L (cd/cm²) | (cd/A) | (lm/W) | efficiency | (hour) | CIE (x, y) |
| Example 1 | 4.24 | 945.45 | 9.45 | 7.00 | 7.98 | 70 | (0.148, |
| | | | | | | | 0.144) |

### Examples 2 (Fabrication of a Blue Fluorescent Organic Electroluminescent Device)

Except for replacing the electron transport material, ET, of Example 1 with ET2 (ET2 is a product name from E-ray Optoelectronics Tech Co. Ltd, Taiwan), example 2 has the same layer structure as described in Example 1. The device structure may be denoted as ITO/HI/HT/HT2/compound C:BH/Liq:ET2/LiF/Al.

The organic electroluminescent device was connected to an external power source, and operated under a direct current voltage. Characteristics of light emission thereof were determined and shown in Table 2 below. With emitting a blue light, an electroluminescent spectrum of the organic electroluminescent device is as illustrated in FIG. 4.

TABLE 2

| | | | Current | Luminous | External | | |
|---|---|---|---|---|---|---|---|
| | Driving | Luminance | efficiency | efficiency | quantum | T95 | |
| | voltage | L (cd/cm²) | (cd/A) | (lm/W) | efficiency | (hour) | CIE (x, y) |
| Example 2 | 4.31 | 1002.27 | 10.02 | 7.30 | 8.31 | 120 | (0.152, |
| | | | | | | | 0.141) |

### Example 3 (Fabrication of a Top-Emitting Blue Fluorescent Organic Electroluminescent Device)

Prior to being loaded into an evaporation system, a substrate was cleaned and degreased with a solvent and UV ozone. The substrate was then transferred into a vacuum deposition chamber for deposition of all of the layers on top of the substrate. By evaporation on a heated boat under a vacuum of about 10⁻⁶ Torr, each of the layers was deposited in sequence as shown in FIG. 2:

a) an indium tin oxide (ITO) layer, 1100 Å-thick;

b) silver (Ag), 2100 Å-thick;

c) a hole injection layer, 50 Å-thick, HI;

d) a hole transport layer, 1300 Å-thick, HT;

e) a second hole transport layer, 100 Å-thick, HT2;

f) a light emitting layer, 250 Å-thick, including a host emitter, BH, doped with 4 wt % of a guest emitter, compound C;

g) an electron transport layer, 300 Å-thick, including compound ET doped with 50 wt % of quinolinolato-lithium (Liq);

h) a cathode, about 200 Å-thick, including Mg:Ag; and

i) a capping layer, 600 Å-thick, including compound CP.

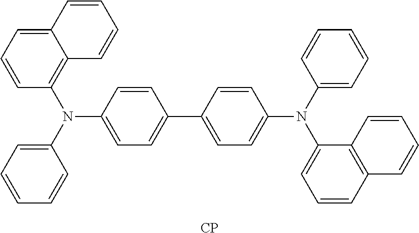 [SMILES: c1ccc(N(c2ccc(-c3ccc(N(c4ccccc4)c4cccc5ccccc45)cc3)cc2)c2cccc3ccccc23)cc1 ; "CP"]

The device structure of Example 3 may be denoted as ITO/Ag/HI/HT/HT2/compound C:BH/Liq:ET/Mg:Ag/CP.

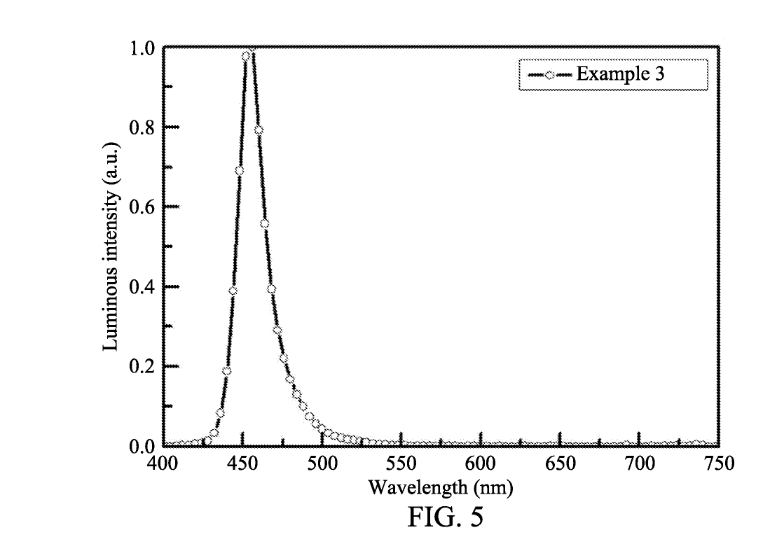

The organic electroluminescent device was connected to an external power source, and operated under a direct current voltage. Characteristics of light emission thereof were determined and shown in Table 3 below. With emitting a blue light, an electroluminescent spectrum of the organic electroluminescent device is as illustrated in FIG. 5.

TABLE 3

| | | | Current | Luminous | External | |
|---|---|---|---|---|---|---|
| | Driving | Luminance | efficiency | efficiency | quantum | |
| | voltage | L (cd/cm²) | (cd/A) | (lm/W) | efficiency | CIE (x, y) |
| Example 3 | 3.83 | 501.21 | 5.01 | 4.11 | 10.39 | (0.145, 0.045) |

As compared with an organic electroluminescent device having a structure of layers fabricated as described in the Examples 1 to 3 above (wherein conventional compounds were used as guest emitters for doping in emitting layers (i.e., not with compounds represented by formula (I) of the present disclosure)), an organic electroluminescent device of the present disclosure, fabricated with a compound represented by formula(I), performed better in terms of a driving voltage, luminance, current efficiency, luminous efficiency, external quantum efficiency, longer lifetime for the device, and blue light colorimetric purity.

The present disclosure is not be limited to the above described embodiments, method and examples, but based on all of the embodiments and methods within the scope and spirit of the present disclosure.

In summary, the organic electroluminescent device of the present disclosure, including a guest emitter represented by formula (I), can have characteristics of low driving voltage, luminance, current efficiency, luminous efficiency, external quantum efficiency, longer lifetime, and blue light colorimetric purity. Therefore, being of an extremely high technical value, the organic electroluminescent device of the present disclosure is applicable to flat panel displays, mobile phone displays, light sources utilizing the characteristics thereof as a planar light emitter, and sign-boards.

The disclosure has been described using exemplary preferred embodiments. However, it is to be understood that the scope of the disclosure is not limited to the disclosed arrangements. The scope of the claims, therefore, should be accorded the broadest interpretation, so as to encompass all such modifications and similar arrangements.

1. An organic electroluminescent device, comprising:
a cathode,
an anode, and
a light emitting layer interposed between the anode and cathode,
wherein the light emitting layer comprises a host emitter and a guest emitter in an amount of 1 wt % to 10 wt %, based on a total weight of the light emitting layer, and wherein the guest emitter is a compound represented by formula (I): 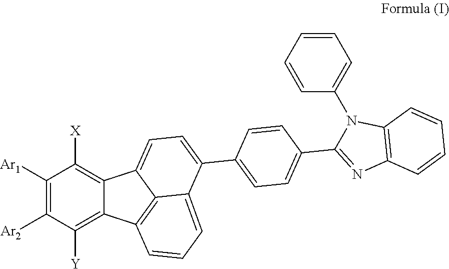
wherein X and Y independently represent hydrogen, or an aryl group or a heteroaryl group having 5 to 10 carbon atoms; X and Y are the same or different; and Ar₁ and Ar₂ independently represent hydrogen, or an unsubstituted or substituted aryl group having 5 to 12 carbon atoms, or Ar₁ and Ar₂ form a fused aromatic ring system together with an attached carbon atom.

2. The organic electroluminescent device of claim 1, wherein the guest emitter is in an amount of 2 wt % to 6 wt %, based on the total weight of the light emitting layer.

3. The organic electroluminescent device of claim 1, wherein the guest emitter has a HOMO-LUMO energy gap of from 2.7 eV to 2.9 eV.

4. The organic electroluminescent device of claim 1, further comprising:
a first hole transport layer comprising a first hole transport material interposed between the light emitting layer and the anode; and
a second hole transport layer comprising a second hole transport material interposed between the light emitting layer and the first hole transport layer.

5. The organic electroluminescent device of claim 4, wherein the first hole transport material has a HOMO energy level of from 5.1 eV to 5.29 eV and the second hole transport material has a HOMO energy level of from 5.3 eV to 5.7 eV.

6. The organic electroluminescent device of claim 4, wherein the host emitter has a HOMO energy level of from 5.7 eV to 5.9 eV.

7. The organic electroluminescent device of claim 1, further comprising a capping layer disposed on the cathode.

8. The organic electroluminescent device of claim 1, further comprising at least one layer selected from the group consisting of a hole injection layer, an electron transport layer, an electron injection layer, a hole blocking layer and an electron blocking layer.

9. The organic electroluminescent device of claim 1, wherein the host emitter is a blue fluorescent emitter.

10. The organic electroluminescent device of claim 1, wherein the aryl group having 5 to 10 carbon atoms of the compound represented by formula (I) is a phenyl group or a naphthyl group.

11. The organic electroluminescent device of claim 1, wherein the heteroaryl group having 5 to 10 carbon atoms of the compound represented by formula (I) is a pyridyl group or

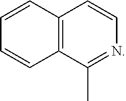

12. The organic electroluminescent device of claim 1, wherein the Ar₁ and Ar₂ of the compound represented by formula (I) independently represent hydrogen or a phenyl group.

13. The organic electroluminescent device of claim 1, wherein the Ar₁ and Ar₂ form a fused benzene ring together with an attached carbon atom.

14. An organic electroluminescent apparatus comprising the organic electroluminescent device of claim 1, which emits white light.
